(19) United States
(12) Patent Application Publication
(10) Pub. No.: US 2002/0034109 A1
(43) Pub. Date: Mar. 21, 2002

(54) Method and apparatus for accessing a memory device

(76) Inventor: Chin-Kuang Luo, Taichung City (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 09/948,189

(22) Filed: Sep. 7, 2001

(30) Foreign Application Priority Data
Sep. 16, 2000 (TW) 089119071

(51) Int. Cl. G11C 7/00

(52) U.S. Cl. 365/200

(57) ABSTRACT

An apparatus for accessing a memory device includes a read/write member adapted to be disposed adjacent to a data storing plane of the memory device, a first moving device for moving the read/write member along a first axis of the data storing plane during data access of the memory device, and a second moving device for moving the read/write member along a second axis of the data storing plane that is transverse to the first axis during data access of the memory device. A method for accessing the memory device is also disclosed.

### BACKGROUND OF THE INVENTION

1. Field of the Invention

The invention relates to a method and apparatus for accessing a memory device, more particularly to a method and apparatus for speedily accessing a memory device.

2. Description of the Related Art

In a conventional disk drive system, such as a hard or optical disk drive, during data access of a disk, the disk can be rotated relative to a central axis, and a read/write head thereof is radially moved relative to the central axis until the read/write head is moved above a desired track for accessing the disk, thereby resulting in an inflexible movement of the read/write head. Furthermore, due to a centrifugal force applied to the rotating disk, wind generated between the rotating disk and the read/write head will result in an unstable movement of the read/write head and an attenuation of the ratio of signal relative to noise.

### SUMMARY OF THE INVENTION

Therefore, the object of the present invention is to provide a method and apparatus for accessing a memory device that can speedily operate data access of the memory device.

According to one aspect of the present invention, a method of accessing a memory device includes the steps of:

disposing a read/write member adjacent to a data storing plane of the memory device; and

during data access of the memory device, moving the read/write member along a first axis of the data storing plane via a first moving device, and along a second axis of the data storing plane that is transverse to the first axis via a second moving device.

According to another aspect of the present invention, an apparatus for accessing a memory device includes a read/write member adapted to be disposed adjacent to a data storing plane of the memory device, a first moving device for moving the read/write member along a first axis of the data storing plane during data access of the memory device, and a second moving device for moving the read/write member along a second axis of the data storing plane that is transverse to the first axis during data access of the memory device.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic circuit block diagram illustrating the preferred embodiment of an apparatus for accessing a memory device according to this invention;

FIG. 2 is a perspective view showing the preferred embodiment; and

FIG. 3 is a schematic view showing a read/write member of the preferred embodiment in states of use.

### DETAILED DESCRIPTION OF THE PREFERRED EMBODIMENT

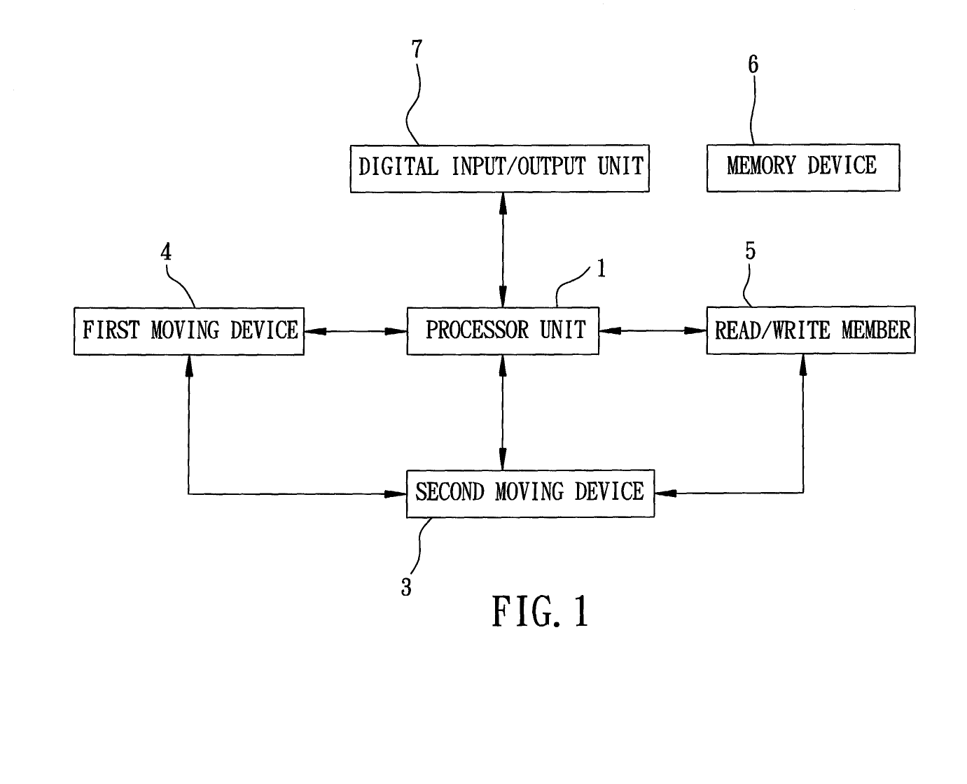

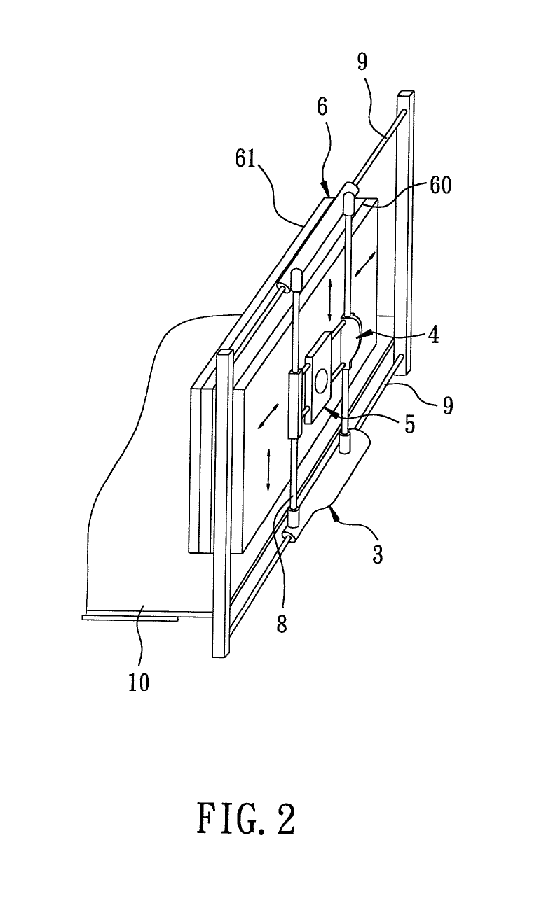

Referring to FIGS. 1 and 2, according to the preferred embodiment of this invention, an apparatus for accessing a memory device is shown to include a first rail unit 8, a second rail unit 9, a read/write member 5, a first moving device 4, a second moving device 3, and a processor unit 1. In this embodiment, the memory device 6 has a plurality of recording layers 60 disposed on a data storing plane 61 (see FIG. 2).

The second rail unit 9 is disposed adjacent to the data storing plane 61 of the memory device 6, and extends along a second axis of the data storing plane 61.

The first rail unit 8 extends along a first axis of data storing plane 61 that is transverse to the second axis. The first rail unit 8 is mounted movably along the second rail unit 9.

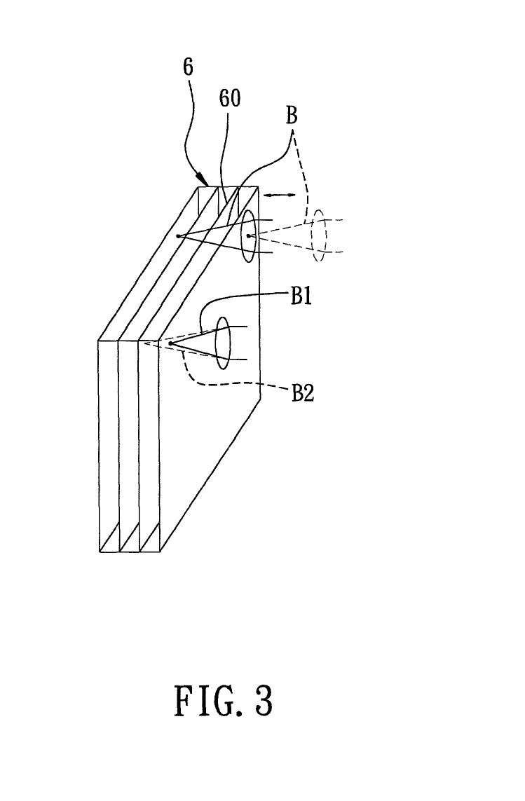

The read/write member 5 is mounted movably along the first rail unit 8. In this embodiment, as shown in FIG. 3, the read/write member 5 is adapted to generate a variable focusing beam (B1, B2) for reading a selected one of the recording layers 60 during data access of the memory device. Furthermore, the read/write member 5 can be a floating-type read/write member that is movable in a third direction transverse to the data storing plane 6 and that is adapted to generate a beam (B) for reading a selected one of the recording layers 60 during data access of the memory device 6.

The first moving device 4 moves the read/write member 5 along the first rail unit 8 during data access of the memory device 6.

The second moving device 3 moves the read/write member 5 along the second rail unit 9 during data access of the memory device 6.

The processor unit 1 (not shown), which can be implemented on a circuit board 10, is coupled to and controls operations of the first and second moving devices 4, 3 and the read/write member 5 during data access of the memory device 6. The data access of the memory device 6 is controlled by the processor unit 1 via a digital input/output unit 7 (not shown) that is coupled to the processor unit 1.

It is noted that the read/write member 5 can be exactly moved by the first and second moving devices 4, 3 via the control of the processor unit 1, thereby resulting in speedy data access of the memory device 6. The object of the invention is thus met.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A method of accessing a memory device, comprising the steps of:
disposing a read/write member adjacent to a data storing plane of the memory device; and
during data access of the memory device, moving the read/write member along a first axis of the data storing plane via a first moving device, and along a second axis of the data storing plane that is transverse to the first axis via a second moving device.

2. The method of claim 1, wherein the read/write member is mounted movably along a first rail unit that extends along the first axis, and the first moving device moves the read/write member along the first rail unit during data access of the memory device.

3. The method of claim 2, wherein the first rail unit is mounted movably along a second rail unit that extends along the second axis, and the second moving device moves the first rail unit along the second rail unit during data access of the memory device.

4. The method of claim 1, wherein the read/write member is an optical read/write member.

5. The method of claim 4, the memory device having a plurality of recording layers that are disposed on the data storing plane, wherein the read/write member is adapted to generate a variable focusing beam for reading a selected one of the recording layers during data access of the memory device.

6. The method of claim 4, the memory device having a plurality of recording layers that are disposed on the data storing plane, wherein the read/write member is a floating-type read/write member that is movable in a third direction transverse to the data storing plane and that is adapted to generate a beam for reading a selected one of the recording layers during data access of the memory device.

7. An apparatus for accessing a memory device, comprising:
a read/write member adapted to be disposed adjacent to a data storing plane of the memory device;
a first moving device for moving said read/write member along a first axis of the data storing plane during data access of the memory device; and
a second moving device for moving said read/write member along a second axis of the data storing plane that is transverse to the first axis during data access of the memory device.

8. The apparatus of claim 7, further comprising a first rail unit that extends along the first axis and that has said read/write member mounted movably therealong, said first moving device moving said read/write member along said first rail unit during data access of the memory device.

9. The apparatus of claim 8, further comprising a second rail unit that extends along the second axis and that has said first rail unit mounted movably therealong, said second moving device moving said first rail unit along said second rail unit during data access of the memory device.

10. The apparatus of claim 7, wherein said read/write member is an optical read/write member.

11. The apparatus of claim 10, the memory device having a plurality of recording layers that are disposed on the data storing plane, wherein said read/write member is adapted to generate a variable focusing beam for reading a selected one of the recording layers during data access of the memory device.

12. The apparatus of claim 10, the memory device having a plurality of recording layers that are disposed on the data storing plane, wherein said read/write member is a floating-type read/write member that is movable in a third direction transverse to the data storing plane and that is adapted to generate a beam for reading a selected one of the recording layers during data access of the memory device.

13. The apparatus of claim 7, further comprising a processor unit coupled to and controlling operations of said first and second moving devices and said read/write member during data access of the memory device.
